(19) United States
(12) Patent Application Publication
(10) Pub. No.: US 2025/0057011 A1
(43) Pub. Date: Feb. 13, 2025

(54) DISPLAY APPARATUS

(71) Applicant: Samsung Display Co., Ltd., Yongin-Si (KR)

(72) Inventors: Jonghwan Shin, Yongin-si (KR); Moosoon Ko, Yongin-si (KR); Yongho Yang, Yongin-si (KR); Yuri Oh, Yongin-si (KR); Kibok Yoo, Yongin-si (KR); Donghyeok Lee, Yongin-si (KR); Jongchan Lee, Yongin-si (KR); Jinsuk Lee, Yongin-si (KR)

(21) Appl. No.: 18/663,084

(22) Filed: May 14, 2024

(30) Foreign Application Priority Data
Aug. 9, 2023 (KR) 10-2023-0104360

(51) Int. Cl. H10K 59/80; H10K 59/122; H10K 102/00

(52) U.S. Cl. CPC H10K 59/8723; H10K 59/122; H10K 2102/351

(57) ABSTRACT

For a display apparatus capable of preventing gas emission from a spacer, the display apparatus includes a substrate, at least one thin-film transistor disposed on the substrate, a pixel electrode layer disposed on the at least one thin-film transistor and including at least one pixel electrode, a pixel-defining layer disposed on the pixel electrode layer and covering edges of the at least one pixel electrode, a spacer disposed on the pixel-defining layer, and a first protective layer disposed on the spacer, wherein the pixel-defining layer includes a trench arranged around the spacer.

### CROSS-REFERENCE TO RELATED APPLICATION

This application is based on and claims priority under 35 U.S.C. § 119 to Korean Patent Application No. 10-2023-0104360, filed on Aug. 9, 2023, in the Korean Intellectual Property Office, the disclosure of which is incorporated by reference herein in its entirety.

### BACKGROUND

### 1. Field

One or more embodiments relate to a display apparatus, and more particularly, to a display apparatus capable of preventing gas emission from a spacer.

### 2. Description of the Related Art

A display apparatus is configured to receive information regarding images and display images. A display apparatus is used as a display of miniaturized products such as mobile phones, and used as a display of large-scale products such as televisions.

A display apparatus includes a plurality of pixels that receive electric signals and emit light to display images to the outside. Each pixel includes a light-emitting element. As an example, an organic light-emitting display apparatus includes an organic light-emitting diode (OLED) as a light-emitting element. Generally, an organic light-emitting display apparatus includes a thin-film transistor and an organic light-emitting diode over a substrate, and operates while the organic light-emitting diode emits light spontaneously.

The display apparatus has an issue of outgassing in which an inner gas is emitted to the outside through a spacer and an issue in which a filler inside an encapsulation seeps out and causes defects in pixels.

### SUMMARY

One or more embodiments include a display apparatus capable of preventing a gas emission phenomenon occurring in a spacer. However, such a technical feature is just an example, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, at least one thin-film transistor disposed on the substrate, a pixel electrode layer disposed on the at least one thin-film transistor and including at least one pixel electrode, a pixel-defining layer disposed on the pixel electrode layer and covering edges of the at least one pixel electrode, a spacer disposed on the pixel-defining layer, and a first protective layer disposed on the spacer, wherein the pixel-defining layer includes a trench arranged around the spacer.

The display apparatus may further include an opposite electrode layer disposed on the pixel-defining layer, and a second protective layer disposed on the first protective layer.

The second protective layer and the opposite electrode layer may include a same material, and the second protective layer may be separated from the opposite electrode layer.

The display apparatus may further include an encapsulation layer disposed on the opposite electrode layer and the second protective layer, and a filler disposed between the opposite electrode layer and the encapsulation layer and disposed between the second protective layer and the encapsulation layer.

The first protective layer may cover an upper surface of the spacer.

At least a portion of lateral surfaces of the spacer may be in contact with the filler between the opposite electrode layer and the second protective layer.

In a plan view, the spacer may be surrounded by the trench.

The opposite electrode layer may cover an inner surface and a bottom surface of the trench.

The pixel electrode layer may include a first pixel electrode and a second pixel electrode apart from the first pixel electrode.

In a plan view, the spacer may be arranged between the first pixel electrode and the second pixel electrode.

The pixel-defining layer may cover edges of the first pixel electrode, include a first opening above at least a central portion of the first pixel electrode, cover edges of the second pixel electrode, and include a second opening above at least a central portion of the second pixel electrode.

In a plan view, the spacer may be arranged between the first opening and the second opening.

The opposite electrode layer and the second protective layer may include a same material and have a same layered structure.

The first protective layer may include indium gallium zinc oxide (IGZO).

A material forming the first protective layer may have an etching selectivity different from an etching selectivity of a material forming the pixel-defining layer.

The first protective layer may have a convex shape facing upward.

The second protective layer may expose at least a central portion of the first protective layer to outside.

An upper surface of at least a central portion of the first protective layer may be flat.

The spacer and the pixel-defining layer may include a same material.

According to one or more embodiments, a display apparatus includes a substrate, at least one thin-film transistor disposed on the substrate, a pixel electrode layer disposed on the at least one thin-film transistor and including at least one pixel electrode, and a pixel-defining layer disposed on the pixel electrode layer and covering edges of the at least one pixel electrode. The pixel-defining layer includes a spacer region having a first thickness, a protrusion region having a second thickness less than the first thickness, and a trench region arranged between the spacer region and the protrusion region in a plan view and having a third thickness less than the second thickness. A first protective layer is disposed on the pixel-defining layer in the spacer region.

The display apparatus may further include an opposite electrode layer on the pixel-defining layer in the protrusion region and the trench region, and a second protective layer disposed on the first protective layer.

The second protective layer and the opposite electrode layer may include a same material, and the second protective layer may be separated from the opposite electrode layer.

The display apparatus may further include an encapsulation layer disposed on the opposite electrode layer and the second protective layer, and a filler disposed between the opposite electrode layer and the encapsulation layer and disposed between the second protective layer and the encapsulation layer.

In a plan view, the spacer region may be surrounded by the trench region.

The second protective layer may expose at least a central portion of the first protective layer.

An upper surface of at least a central portion of the first protective layer may be flat.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a schematic plan view of a display panel of a display apparatus according to an embodiment.

FIG. 2 is an equivalent circuit diagram of a pixel included in the display panel of FIG. 1.

FIG. 3 is a schematic cross-sectional view of a portion of the display panel of FIG. 1.

FIG. 4 is a schematic cross-sectional view of a portion of the display panel of FIG. 1 centered on a spacer.

FIG. 5 is a schematic cross-sectional view of the spacer and a first protective layer of FIG. 4.

FIG. 6 is a schematic cross-sectional view of an example in which a filler and an encapsulation layer are formed in FIG. 5.

FIG. 7 is a cross-sectional view of an example in which the spacer and the first protective layer of FIG. 6 are pressed by a mask.

FIG. 8 is a schematic plan view of an arrangement of a spacer in a case where a pixel configuration of the display panel of FIG. 1 is a first configuration.

FIG. 9 is a schematic plan view of an arrangement of a spacer in a case where a pixel configuration of the display panel of FIG. 1 is a second configuration.

FIG. 10 is a schematic plan view of an arrangement of a spacer in a case where a pixel configuration of the display panel of FIG. 1 is a third configuration.

FIG. 11 is a schematic cross-sectional view of outgassing from a spacer of a display apparatus according to a comparative example.

FIG. 12 is a photo showing a filler of a display apparatus according to a comparative example penetrating into a pixel electrode.

FIG. 13 is a view showing an example of a process of forming the spacer and the first protective layer of FIGS. 4 to 7.

FIG. 14 is a view showing another example of a process of forming the spacer and the first protective layer of FIGS. 4 to 7.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings.

However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

As used herein, when various elements such as a layer, a region, a plate, and the like are disposed “on” another element, not only the elements may be disposed “directly on” the other element, but another element may be disposed therebetween. In addition, sizes of elements in the drawings may be exaggerated or reduced for convenience of explanation. As an example, the size and thickness of each element shown in the drawings are arbitrarily represented for convenience of description, and thus, the disclosure is not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

Hereinafter, a display apparatus according to an embodiment is described in detail.

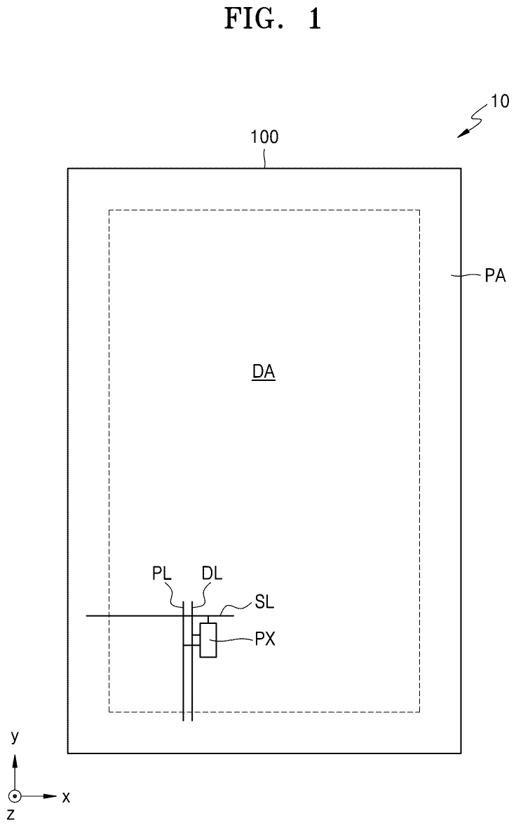

FIG. 1 is a schematic plan view of a display panel 10 of a display apparatus according to an embodiment.

As shown in FIG. 1, the display apparatus according to an embodiment includes the display panel 10. As long as the display apparatus includes the display panel 10, any display apparatus may be used. As an example, the display apparatus may include various apparatuses such as smartphones, tablet computers, laptop computers, televisions, advertisement boards, or the like. A display apparatus according to an embodiment includes thin-film transistors, a capacitor, and the like, the thin-film transistors, the capacitor, and the like may be implemented by conductive layers and insulating layers.

The display panel 10 includes a display area DA and a peripheral area PA outside the display area DA. It is shown in FIG. 1 that the display area DA has a rectangular shape. However, the embodiment is not limited thereto. The display area DA may have various shapes, for example, circular shapes, elliptical shapes, polygonal shapes, or shapes of specific figures.

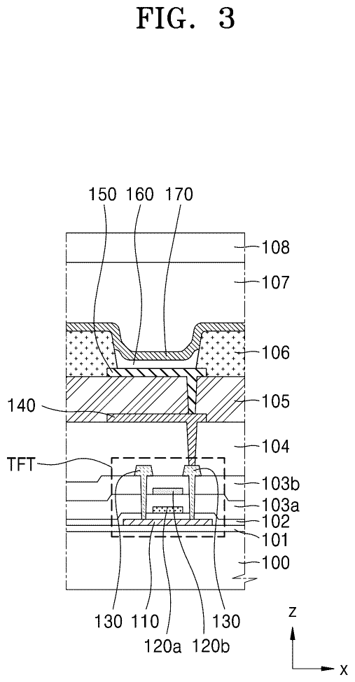

The display area DA is a region in which images are displayed, and a plurality of pixels PX may be arranged in the display area DA. Each pixel PX may include a light-emitting element such as an organic light-emitting diode. Each pixel PX may be configured to emit, for example, red, green, or blue light. The pixel PX may be connected to a pixel circuit including a thin-film transistor portion TFT (e.g., see FIG. 3), a storage capacitor, and the like. The pixel circuit may be connected to a scan line SL, a data line DL, and a driving voltage line PL, wherein the scan line SL is configured to transfer scan signals, the data line DL crosses the scan line SL and is configured to transfer data signals, and the driving voltage line PL is configured to supply a driving voltage. The scan line SL may extend in an x direction (sometimes referred to as a second direction), the data line DL and the driving voltage line PL may extend in a y direction (sometimes referred to as a first direction).

The pixel PX may be configured to emit light of a brightness corresponding to an electrical signal from the pixel circuit electrically connected thereto. The display area DA may be configured to display preset images by using light emitted from the pixel PX. For reference, as described above, the pixel PX may be defined as an emission area that is configured to emit light having one of red, green, and blue.

The peripheral area PA is a region in which pixels PX are not arranged and may be a region that is configured not to display images. A power supply line for driving the pixel PX and the like may be arranged in the peripheral area PA. In addition, pads may be arranged in the peripheral area PA, and a printed circuit board including a driving circuit portion, or an integrated circuit element such as a driver integrated circuit (IC) may be arranged to be electrically connected to the plurality of pads.

For reference, because the display panel 10 includes a substrate 100, it may be understood that the substrate 100 includes the display area DA and the peripheral area PA. The substrate 100 is described below in detail.

In addition, a plurality of transistors may be arranged in the display area DA. In the plurality of transistors, a first terminal of a transistor may be a source electrode or a drain electrode, and a second terminal may be an electrode different from the first terminal depending on the kind (an N type or a P type) of the transistor and/or an operation condition. As an example, in the case where the first terminal is a source electrode, the second terminal may be a drain electrode.

The plurality of transistors may include a driving transistor, a data-write transistor, a compensation transistor, an initialization transistor, and an emission control transistor.

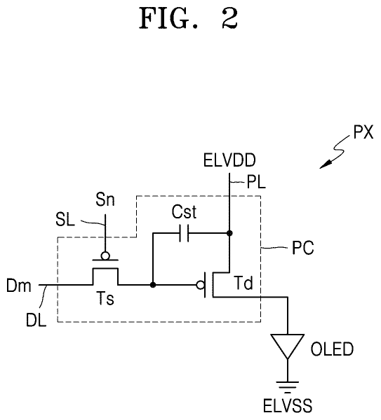

The driving transistor may be connected between the driving voltage line PL and an organic light-emitting diode OLED (e.g., see FIG. 2), and the data-write transistor may be connected to the data line DL and the driving transistor and configured to perform a switching operation of transferring a data signal transferred through the data line DL.

The compensation transistor may be turned on according to a scan signal transferred through the scan line SL and configured to compensate for a threshold voltage of the driving transistor by connecting the driving transistor to the organic light-emitting diode OLED.

The initialization transistor may be turned on according to a scan signal transferred through the scan line SL and configured to initialize a gate electrode of the driving transistor by transferring an initialization voltage to the gate electrode of the driving transistor. A scan line connected to the initialization transistor may be a separate scan line different from a scan line connected to the compensation transistor.

The emission control transistor may be turned on according to an emission control signal transferred through an emission control line, and as a result, a driving current may flow through the organic light-emitting diode OLED.

The organic light-emitting diode OLED may include a pixel electrode (an anode) and an opposite electrode (a cathode), and an opposite electrode layer may be configured to receive a second power voltage ELVSS. The organic light-emitting diode OLED may be configured to display images by receiving the driving current from the driving transistor and emitting light.

Hereinafter, although an organic light-emitting display apparatus is described as an example of the display apparatus according to an embodiment, the display apparatus is not limited thereto. In an embodiment, the display apparatus may be an inorganic light-emitting display apparatus or a quantum-dot light-emitting display apparatus. As an example, an emission layer of a display element of the display apparatus may include an organic material or an inorganic material. In addition, the display apparatus may include an emission layer and quantum-dots disposed on a path of light emitted from the emission layer.

FIG. 2 is an equivalent circuit diagram of a pixel PX included in the display panel of FIG. 1.

As shown in FIG. 2, each pixel PX may include a pixel circuit PC and the organic light-emitting diode OLED connected to the pixel circuit PC, wherein the pixel circuit PC is connected to the scan line SL and the data line DL.

The pixel circuit PC includes a driving thin-film transistor Td, a switching thin-film transistor Ts, and a storage capacitor Cst. The switching thin-film transistor Ts is connected to the scan line SL and the data line DL, and configured to transfer a data signal Dm to the driving thin-film transistor Td according to a scan signal Sn, wherein the data signal Dm is input through the data line DL, and the scan signal Sn is input through the scan line SL.

The storage capacitor Cst may be connected to the switching thin-film transistor Ts and the driving voltage line PL and configured to store a voltage corresponding to a difference between a voltage transferred from the switching thin-film transistor Ts and a first power voltage ELVDD supplied to the driving voltage line PL.

The second power voltage ELVSS may be a driving voltage having a relatively low level compared to the first power voltage ELVDD. The level of the driving voltage supplied to each pixel PX may be a difference between the levels of the first power voltage ELVDD and the second power voltage EVLSS.

The driving thin-film transistor Td may be connected to the driving voltage line PL and the storage capacitor Cst and configured to control a driving current according to the voltage stored in the storage capacitor Cst, the driving current flowing from the driving voltage line PL to the organic light-emitting diode OLED. The organic light-emitting diode OLED may be configured to emit light having a preset brightness corresponding to the driving current.

Although it is described with reference to FIG. 2 that the pixel circuit PC includes two thin-film transistors and one storage capacitor, the embodiment is not limited thereto.

The pixel circuit PC may include two or more storage capacitors.

FIG. 3 is a schematic cross-sectional view of a portion of the display panel of FIG. 1.

As described above, the substrate 100 may include the display area DA and regions corresponding to the peripheral area PA outside the display area DA. The substrate 100 may include various flexible or bendable materials. As an example, the substrate 100 may include glass, metal, or a polymer resin. In addition, the substrate 100 may include a polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the polymer resin, and a barrier layer including an inorganic material (such as silicon oxide, silicon nitride, and silicon oxynitride) therebetween. However, various modifications may be made.

A buffer layer 101 may be disposed on the substrate 100. The buffer layer 101 may prevent impurity ions from diffusing, prevent penetration of moisture or external air, and serve as a barrier layer for planarizing a surface and/or a blocking layer. The buffer layer 101 may include silicon oxide, silicon nitride, or silicon oxynitride. In addition, the buffer layer 101 may allow a semiconductor layer 110 to be uniformly crystallized by adjusting a heat providing speed during a crystallization process for forming the semiconductor layer 110.

The semiconductor layer 110 may be disposed on the buffer layer 101. The semiconductor layer 110 may include polycrystalline silicon and include a channel region, a source region, and a drain region, wherein the channel region is not doped with impurities, and the source region and the drain region are on two opposite sides of the channel region and doped with impurities. Here, the impurities may change depending on the kind of a thin-film transistor. The impurities may be N-type impurities or P-type impurities.

A gate insulating layer 102 may be disposed on the semiconductor layer 110. The gate insulating layer 102 may be a configuration for securing insulation between the semiconductor layer 110 and a first gate layer 120a. The gate insulating layer 102 may include an inorganic material such as silicon oxide, silicon nitride, and/or silicon oxynitride, and may be disposed between the semiconductor layer 110 and the first gate layer 120a. The gate insulating layer 102 may have a shape corresponding to the entire surface of the substrate 100 and have a structure in which contact holes are formed in preset portions thereof. As described above, the insulating layer including the inorganic material may be formed by chemical vapor deposition (CVD) or atomic layer deposition (ALD). This is also applicable to embodiments below and modifications thereof.

The first gate layer 120a may be disposed on the gate insulating layer 102. The first gate layer 120a may be disposed at a position overlapping the semiconductor layer 110 vertically and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), and titanium (Ti), tungsten (W), and copper (Cu).

A first interlayer insulating layer 103a may be disposed on the first gate layer 120a. The first interlayer insulating layer 103a may cover the first gate layer 120a. The first interlayer insulating layer 103a may include an inorganic material. As an example, the first interlayer insulating layer 103a may include metal oxide or metal nitride, and specifically, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). In an embodiment, the first interlayer insulating layer 103a may have a dual structure of SiOₓ/SiN_{y} or SiNₓ/SiO_{y}.

A second gate layer 120b may be disposed on the first interlayer insulating layer 103a. The second gate layer 120b may be disposed at a position overlapping the first gate layer 120a vertically and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), and titanium (Ti), tungsten (W), and copper (Cu).

The second gate layer 120b may form the storage capacitor Cst described with reference to FIG. 2 in cooperation with the first gate layer 120a. The first gate layer 120a may include a first electrode portion of the storage capacitor Cst, and the second gate layer 120b may include a second electrode portion of the storage capacitor Cst.

When viewed in a direction perpendicular to the substrate 100, the area of the second gate layer 120b may be greater than the area of the first gate layer 120a. In an embodiment, when viewed in a direction perpendicular to the substrate 100, the second gate layer 120b may cover the first gate layer 120a.

A second interlayer insulating layer 103b may be disposed on the second gate layer 120b. The second interlayer insulating layer 103b may cover the second gate layer 120b. The second interlayer insulating layer 103b may include an inorganic material. As an example, the second interlayer insulating layer 103b may include metal oxide or metal nitride, and specifically, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). In an embodiment, the second interlayer insulating layer 103b may have a dual structure of SiOₓ/SiN_{y} or SiNₓ/SiO_{y}.

A first conductive layer 130 may be disposed on the second interlayer insulating layer 103b. The first conductive layer 130 may serve as an electrode connected to source/drain regions of the semiconductor layer through contact holes included in the second interlayer insulating layer 103b, the first interlayer insulating layer 103a, and the gate insulating layer 102. The first conductive layer 130 may include at least one metal among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). As an example, the first conductive layer 130 may include a Ti layer, an Al layer, and/or a Cu layer.

A first organic insulating layer 104 may be disposed on the first conductive layer 130. The first organic insulating layer 104 may cover the upper portion of the first conductive layer 130, have an approximately flat upper surface, and may be an organic insulating layer serving as a planarization layer. The first organic insulating layer 104 may include, for example, acryl, benzocyclobutene (BCB), or hexamethyldisiloxane (HMDSO). The first organic insulating layer 104 may include a single layer or a multi-layer. However, various modifications may be made.

A second conductive layer 140 may be disposed on the first organic insulating layer 104. The second conductive layer 140 may serve as an electrode connected to source/drain regions of the semiconductor layer through contact holes included in the first organic insulating layer 104. The second conductive layer 140 may include at least one metal among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). As an example, the second conductive layer 140 may include a Ti layer, an Al layer, and/or a Cu layer.

A second organic insulating layer 105 may be disposed on the first conductive layer 130. The second organic insulating layer 105 may cover the first conductive layer 130, have an approximately flat upper surface, and may be an organic insulating layer serving as a planarization layer. The second organic insulating layer 105 may include, for example, acryl, benzocyclobutene (BCB), or hexamethyldisiloxane (HMDSO). The second organic insulating layer 105 may include a single layer or a multi-layer. However, various modifications may be made.

In addition, although not shown in FIG. 3, an additional conductive layer and an additional insulating layer may be disposed between the conductive layer and the pixel electrode, and applicable to various embodiments. In this case, the additional conductive layer may include the same material as a material of the conductive layer and have the same layered structure as a structure of the conductive layer. The additional insulating layer may include the same material as a material of the organic insulating layer and have the same layered structure as a structure of the organic insulating layer.

A pixel electrode layer 150 may be disposed on the second organic insulating layer 105. The pixel electrode layer 150 may be connected to the second conductive layer 140 through a contact hole formed in the second organic insulating layer 105. A display element may be disposed on the pixel electrode layer 150. An organic light-emitting diode may be used as the display element. That is, the organic light-emitting diode may be disposed on, for example, the pixel electrode layer 150. The pixel electrode layer 150 may include a light-transmissive conductive layer and a reflective layer, wherein the light-transmissive conductive layer includes a light-transmissive conductive oxide such as indium tin oxide (ITO), indium oxide (In₂O₃), or indium zinc oxide (IZO), and the reflective layer includes metal such as aluminum (Al) or silver (Ag). As an example, the pixel electrode layer 150 may have a three-layered structure of ITO/Ag/ITO.

Although, for convenience of description, the pixel electrode layer 150 is shown as a pixel electrode corresponding to one pixel in FIG. 3, the pixel electrode layer 150 may denote a construction including pixel electrodes respectively arranged in every pixel. As an example, the pixel electrode layer 150 may be used as a term including a first pixel electrode and a second pixel electrode described below.

A pixel-defining layer 106 may be disposed on the second organic insulating layer 105 and arranged to cover the edges of the pixel electrode layer 150. The pixel-defining layer 106 may cover the edges of the pixel electrode layer 150. The pixel-defining layer 106 has an opening corresponding to the pixel, and the opening may be formed to expose at least the central portion of the pixel electrode layer 150. As an example, the pixel-defining layer 106 may include an opening corresponding to at least a central portion of the pixel electrode layer 150.

The pixel-defining layer 106 may include an organic material such as polyimide or HMDSO.

An intermediate layer 160 and an opposite electrode layer 170 may be disposed in the opening of the pixel-defining layer 106. The intermediate layer 160 may include a low-molecular weight material or a polymer material. In the case where the intermediate layer 160 includes a low-molecular weight material, the intermediate layer 160 may include a hole injection layer, a hole transport layer, an electron transport layer, and/or an electron injection layer. In the case where the intermediate layer 160 includes a polymer material, the intermediate layer 160 may generally have a structure including the hole transport layer and the emission layer.

The opposite electrode layer 170 may include a light-transmissive conductive layer including a light-transmissive conductive oxide such as ITO, In₂O₃, or IZO. The pixel electrode layer 150 is used as an anode, and the opposite electrode layer 170 is used as a cathode. The polarities of the electrodes may be reversely applied.

The structure of the intermediate layer 160 is not limited thereto and may have various structures. As an example, at least one of layers constituting the intermediate layer 160 may be integrally formed like the opposite electrode layer 170. In an embodiment, the intermediate layer 160 may include a layer patterned to correspond to each of a plurality of pixel electrode layers 150.

The opposite electrode layer 170 may be arranged in the upper portion of the display area DA and arranged over the entire surface of the display area DA. That is, the opposite electrode layer 170 may be integrally formed to cover the plurality of pixels. The opposite electrode layer 170 may be in electrical contact with a common power supply line (not shown) arranged in the peripheral area PA.

An encapsulation layer 108 may be disposed on the opposite electrode 170. The encapsulation layer 108 may be a layer for encapsulating an organic light-emitting element. The encapsulation layer 108 may include glass. Sealant (not shown) may be disposed between the substrate 100 and the encapsulation layer 108. The sealant (not shown) may be arranged in the peripheral area PA and arranged to surround the display area DA. Because the sealant (not shown) is arranged along the circumference of the display area DA, penetration of moisture and the like into the display area DA through the lateral surface of the display apparatus may be prevented or reduced.

A filler 107 may be disposed in an empty space between the encapsulation layer 108 and the opposite electrode layer 170, or between the encapsulation layer 108 and another element. As an example, the filler 107 may fill a space between the encapsulation layer 108 and the opposite electrode layer 170. As an example, the filler 107 may include a material such as an epoxy-based material, acrylate-based material, and epoxy-acrylate-based material.

As shown in FIG. 3, the semiconductor layer 110, the first gate layer 120a, and the second gate layer 120b may configure the thin-film transistor portion TFT. The thin-film transistor portion TFT may serve as one of the thin-film transistors included in the pixel circuit PC described with reference to FIG. 2.

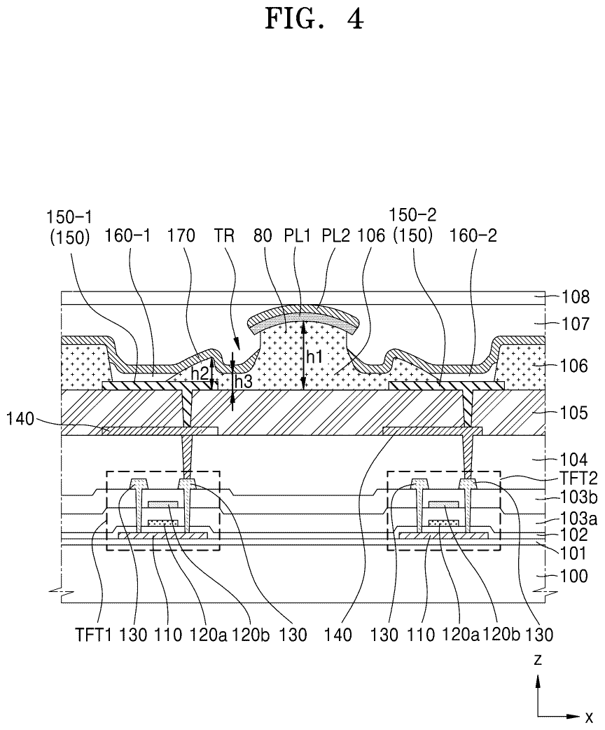

FIG. 4 is a schematic cross-sectional view of a portion, mainly, a spacer 80 of the display panel of FIG. 1. For reference, in the description of FIG. 4, contents identical to or repeating those described with reference to FIGS. 1 to 3 may be omitted.

As shown in FIG. 4, the display apparatus according to an embodiment may include the substrate 100, at least one thin-film transistor disposed on the substrate 100, the pixel electrode layer 150 disposed on the at least one thin-film transistor, the pixel-defining layer 106 disposed on the pixel electrode layer 150, the spacer 80 disposed on the pixel-defining layer 106, and a first protective layer PL1 disposed on the spacer 80. In this case, the at least one thin-film transistor may denote the thin-film transistor portion TFT described above, a first thin-film transistor TFT1 described below, a second thin-film transistor TFT2 described below, and the like.

The pixel electrode layer 150 may include at least one pixel electrode (e.g., a first pixel electrode 150-1 and a second pixel electrode 150-2), and the pixel-defining layer 106 may cover the edges of the at least one pixel electrode. As an example, the pixel-defining layer 106 may cover the edges of the first pixel electrode 150-1 and expose at least a central portion of the first pixel electrode 150-1. In addition, the pixel-defining layer 106 may cover the edges of the second pixel electrode 150-2 and expose at least a central portion of the second pixel electrode 150-2.

As an example, the pixel-defining layer 106 may cover the edges of the first pixel electrode 150-1 and include a first opening corresponding to the at least a central portion of the first pixel electrode 150-1. The at least a central portion of the first pixel electrode 150-1 may be exposed through the first opening. The at least central portion of the first pixel electrode 150-1 may correspond to one pixel.

As an example, the pixel-defining layer 106 may cover the edges of the second pixel electrode 150-2 and include a second opening corresponding to the at least a central portion of the second pixel electrode 150-2. The at least central portion of the second pixel electrode 150-2 may be exposed through the second opening. The at least central portion of the second pixel electrode 150-2 may correspond to another pixel.

As an example, the spacer 80 may be arranged between the first opening and the second opening in a plan view.

The spacer 80 may be arranged in the peripheral area PA or the display area DA. Depending on the case, the spacer 80 may include the same material as the pixel-defining layer 106. The spacer 80 may prevent the organic light-emitting diode OLED from being damaged by sagging of a mask in the manufacturing process that uses the mask. The spacer 80 may include an organic insulating material and include a single layer or a multi-layer.

The display apparatus according to an embodiment may further include the opposite electrode layer 170 disposed on the pixel-defining layer 106, and a second protective layer PL2 disposed on the first protective layer PL1. The second protective layer PL2 may include the same material as the opposite electrode layer 170. The second protective layer PL2 may include the same layered structure as the opposite electrode layer 170. As an example, the second protective layer PL2 and the opposite electrode layer 170 may be simultaneously formed during the same process. As a result, the structure of the opposite electrode layer 170 may be the same as the structure of the second protective layer PL2. The second protective layer PL2 may be separated from the opposite electrode layer 170 by an undercut process or an etching process. The second protective layer PL2 and the opposite electrode layer 170 may be separated from each other spatially and physically. As a result of separation, at least a portion of the lateral surface of the spacer 80 may be exposed to the outside between the opposite electrode layer 170 and the second protective layer PL2. That is, at least a portion of the lateral surface of the spacer 80 exposed to the outside may be in direct contact with the filler 107.

The display apparatus according to an embodiment may further include the encapsulation layer 108 and the filler 107, wherein the encapsulation layer 108 is disposed on the opposite electrode layer 170 and the second protective layer PL2, and the filler 107 is disposed between the opposite electrode layer 170 and the second protective layer PL2, and the encapsulation layer 108. The filler 107 may be separated or apart from the upper surface of the spacer 80 by the first protective layer PL1. That is, the filler 107 may not be in contact with the upper surface of the spacer 80 due to the first protective layer PL1. One of the roles of the first protective layer PL1 may be to prevent the filler 107 from being in contact with the upper surface of the spacer 80.

The pixel-defining layer 106 may include a trench TR. The trench TR included in the pixel-defining layer 106 may be arranged around the spacer 80. In a plan view, the trench TR may be arranged to surround the spacer 80. The trench TR may have a shape dug to a preset depth. Because the trench TR has a hollow shape, the trench TR has an inner lateral surface and a bottom surface.

The opposite electrode layer 170 may cover the inner lateral surface and the bottom surface of the trench TR. The opposite electrode layer 170 may cover a partial region of the lateral surface of the spacer 80 beyond the trench TR or cover the periphery of the lateral surface of the spacer 80.

As shown in FIG. 4, the first thin-film transistor portion TFT1, the second thin-film transistor portion TFT2, the first pixel electrode 150-1, and the second pixel electrode 150-2 may be provided. The first thin-film transistor portion TFT1 may correspond to the first pixel electrode 150-1. The first thin-film transistor portion TFT1 may be an example of the thin-film transistor portion TFT described with reference to FIG. 3. Accordingly, the first thin-film transistor portion TFT1 may include the semiconductor layer 110, the first gate layer 120a, and the second gate layer 120b.

The second thin-film transistor portion TFT2 may correspond to the second pixel electrode 150-2. The second thin-film transistor portion TFT2 may be another example of the thin-film transistor portion TFT described with reference to FIG. 3. Accordingly, the second thin-film transistor portion TFT2 may also include the semiconductor layer 110, the first gate layer 120a, and the second gate layer 120b.

The first pixel electrode 150-1 and the second pixel electrode 150-2 may be included in the pixel electrode layer 150. That is, an entire layer in which the first pixel electrode 150-1 and the second pixel electrode 150-2 are located may be referred to as the pixel electrode layer 150. The edges of each of the first pixel electrode 150-1 and the second pixel electrode 150-2 may be covered by the pixel-defining layer 106.

A first intermediate layer 160-1 and a second intermediate layer 160-2 may be also included in the intermediate layer 160. That is, an entire layer in which the first intermediate layer 160-1 and the second intermediate layer 160-2 are located may be referred to as the intermediate layer 160. The first intermediate layer 160-1 may be an element corresponding to the first pixel electrode 150-1, and the second intermediate layer 160-2 may be an element corresponding to the second pixel electrode 150-2.

The pixel-defining layer 106 may expose at least a central portion of the first pixel electrode 150-1 to the outside. As a result, the first intermediate layer 160-1 may be disposed on the at least central portion of the first pixel electrode 150-1. The pixel-defining layer 106 may expose at least a central portion of the second pixel electrode 150-2 to the outside. As a result, the second intermediate layer 160-2 may be disposed on the at least central portion of the second pixel electrode 150-2.

In a plan view, the spacer 80 may be arranged between the first pixel electrode 150-1 and the second pixel electrode 150-2. In a plan view, the spacer 80 may be arranged between at least a central portion of the first pixel electrode 150-1 and at least a central portion of the second pixel electrode 150-2. In a plan view, the spacer 80 may be arranged between the first opening of the pixel-defining layer 106 above the first pixel electrode 150-1 and the second opening of the pixel-defining layer 106 above the second pixel electrode 150-2.

In addition, the trench TR has a thickness in which the first pixel electrode 150-1 and the second pixel electrode 150-2 are not exposed to the outside.

As shown in FIG. 4, the first protective layer PL1 may be disposed on the spacer 80. The first protective layer PL1 may cover the upper surface of the spacer 80. As an example, the first protective layer PL1 may include indium gallium zinc oxide (IGZO). In an embodiment, the first protective layer PL1 may include a material having an etching selectivity different from an etching selectivity of the pixel-defining layer 106. A material forming the first protective layer PL1 may have an etching selectivity different from an etching selectivity of a material forming the pixel-defining layer 106.

As an example, in a dry etching process under a specific condition, an etching selectivity of a material forming the first protective layer PL1 may be less than an etching selectivity of a material forming the spacer 80. Accordingly, when the dry etching process of the specific condition is applied to the spacer 80 and the first protective layer PL1 covering the upper surface of the spacer 80, the spacer 80 and the first protective layer PL1 may have an undercut structure. That is, in a plan view, the area of the first protective layer PL1 is formed greater than the area of the upper surface of the spacer 80. As a result, the damage to the first protective layer PL1 and the exposure of the upper surface of the spacer 80 by a mask process which will be performed afterwards may be prevented or reduced.

In other words, the first protective layer PL1 may be a construction configured to prevent an outgassing phenomenon occurring inside the spacer 80. In a plan view, the width of the first protective layer PL1 may be greater than the width of the upper surface of the spacer 80.

The second protective layer PL2 may be disposed on the first protective layer PL1. The second protective layer PL2 may include the same material as the opposite electrode layer 170. The second protective layer PL2 and the opposite electrode layer 170 may be separated from each other. The second protective layer PL2 and the opposite electrode layer 170 may be simultaneously formed. At least a portion of the lateral surface of the spacer 80 may be exposed between the second protective layer PL2 and the opposite electrode layer 170. As a result of exposure, at least a portion of the lateral surface of the spacer 80 may be in contact with the filler 107.

The upper surface of the spacer 80 may have a convex shape upwardly.

Accordingly, the first protective layer PL1 covering the upper surface of the spacer 80 may also have an upwardly convex shape. In addition, the second protective layer PL2 covering the first protective layer PL1 may also have an upwardly convex shape.

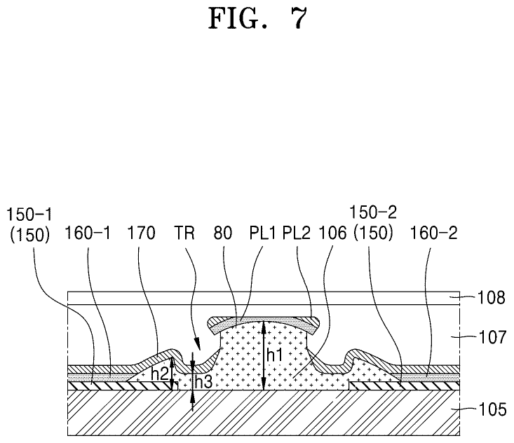

The spacer 80, the first protective layer PL1, and the second protective layer PL2 may be pressed or partially damaged by the mask used in the process. A portion of the second protective layer PL2 may be damaged by the mask used in the process, and as a result thereof, at least a portion of the first protective layer PL1 may be exposed outside the second protective layer PL2. Contents thereof are described with reference to FIG. 7.

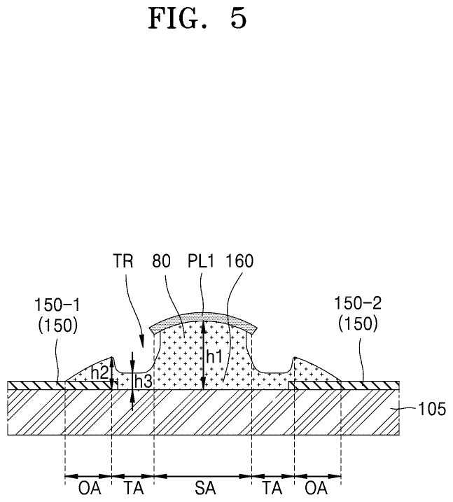

FIG. 5 is a schematic cross-sectional view of the spacer 80 and the first protective layer PL1 of FIG. 4. For reference, in the description of FIG. 5, contents identical to or repeating those described with reference to FIGS. 1 to 4 may be omitted.

As shown in FIG. 5, the spacer 80 is included in the pixel-defining layer 106 and may be described as a region of the pixel-defining layer 106. As an example, the pixel-defining layer 106 may include a spacer area SA having a first thickness h1, a protrusion area OA having a second thickness h2, and a trench area TA having a third thickness h3. The second thickness h2 may be less than the first thickness h1, and the third thickness h3 may be less than the second thickness h2.

The first thickness h1 may denotes a largest value among the thickness of the exact center of the spacer area SA or the thickness of the spacer area SA in FIG. 5. The second thickness h2 may denote a largest value among thicknesses of the protrusion area OA in FIG. 5 or the thickness of a boundary region between the protrusion area OA and the trench area TA. The third thickness h3 may denote a smallest value among the thicknesses of the trench area TA in FIG. 5.

However, the trench area TA of the pixel-defining layer 106 has a thickness of a size by which the first pixel electrode 150-1 and the second pixel electrode 150-2 are not exposed to the outside.

The spacer area SA may prevent the organic light-emitting diode OLED from being damaged by sagging of a mask in the manufacturing process that uses the mask.

In a plan view, the spacer area SA may be surrounded by the trench area TA. As an example, a portion of the protrusion area OA and the trench area TA of the pixel-defining layer 106 may cover the edges of the pixel electrode layer 150. As an example, a portion of the trench area TA of the pixel-defining layer 106 may cover the end of the pixel electrode layer 150.

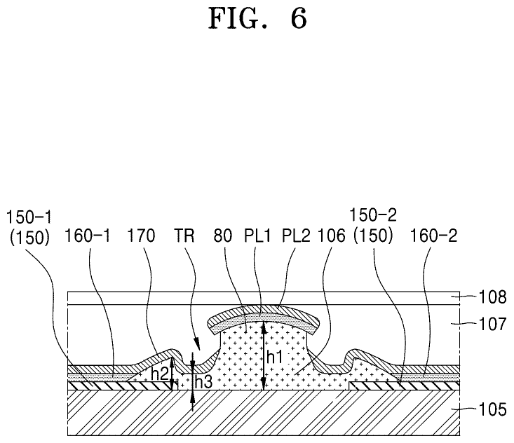

The first protective layer PL1 may cover the upper surface of the spacer area SA of the pixel-defining layer 106. In a plan view, a portion of the edges of the first protective layer PL1 may overlap the trench area TA. In a plan view, the first protective layer PL1 may be arranged between the first pixel electrode 150-1 and the second pixel electrode 150-2. In a plan view, the spacer area SA may be arranged between the first pixel electrode 150-1 and the second pixel electrode 150-2. Likewise, in a plan view, the second protective layer PL2 (e.g., see FIG. 6) may be arranged between the first pixel electrode 150-1 and the second pixel electrode 150-2.

FIG. 6 is a schematic cross-sectional view of an example in which the filler 107 and the encapsulation layer 106 as well as additional elements are formed to FIG. 5. For reference, in the description of FIG. 6, contents identical to or repeating those described with reference to FIGS. 1 to 4 may be omitted.

As shown in FIG. 6, the second protective layer PL2 may cover the upper surface of the first protective layer PL1. The second protective layer PL2 may include the same material as the opposite electrode layer 170 and be simultaneously during the same process. However, the second protective layer PL2 may be separated from the opposite electrode layer 170, and the lateral surface of the spacer 80 may be exposed between the second protective layer PL2 and the opposite electrode layer 170.

A portion of the intermediate layer 160 disposed on the first pixel electrode 150-1 may be referred to as the first intermediate layer 160-1, and a portion of the intermediate layer 160 disposed on the second pixel electrode 150-2 may be referred to as the second intermediate layer 160-2. The intermediate layer 160 may include a plurality of layers.

Unlike the drawing, some of the plurality of layers forming the intermediate layer 160 may cover the protrusion area OA and the trench area TA of the pixel-defining layer 106 in cooperation with the opposite electrode layer 170. In this case, a material included in some of the plurality of layers forming the intermediate layer 160 may be equally also included in the second protective layer PL2.

FIG. 7 is a cross-sectional view of an example in which the spacer 80 and the first protective layer PL1 of FIG. 6 are pressed by the mask. For reference, in the description of FIG. 7, contents identical to or repeating those described with reference to FIGS. 1 to 6 may be omitted.

As shown in FIG. 7, the first protective layer PL1 and the second protective layer PL2 may be pressed by the mask used in the manufacturing process. As a result, the second protective layer PL2 may be partially damaged, and the first protective layer PL1 may be exposed to the outside due to the partial damage of the second protective layer PL2 and be in direct contact with the filler 107. A portion of the first protective layer PL1 exposed to the outside may have a generally flat shape as a result of being pressed by the mask. That is, the first protective layer PL1 and the second protective layer PL2 may be pressed or damaged by the mask used in the manufacturing process, and in the case where a portion of the second protective layer PL2 is damaged, the first protective layer PL1 may be exposed to the outside and be in direct contact with the filler 107.

As described above, even though the first protective layer PL1 and the second protective layer PL2 are pressed or damaged by the mask used in the manufacturing process, an outgassing phenomenon that a gas is emitted to the outside through the spacer 80 may be prevented by the first protective layer PL1.

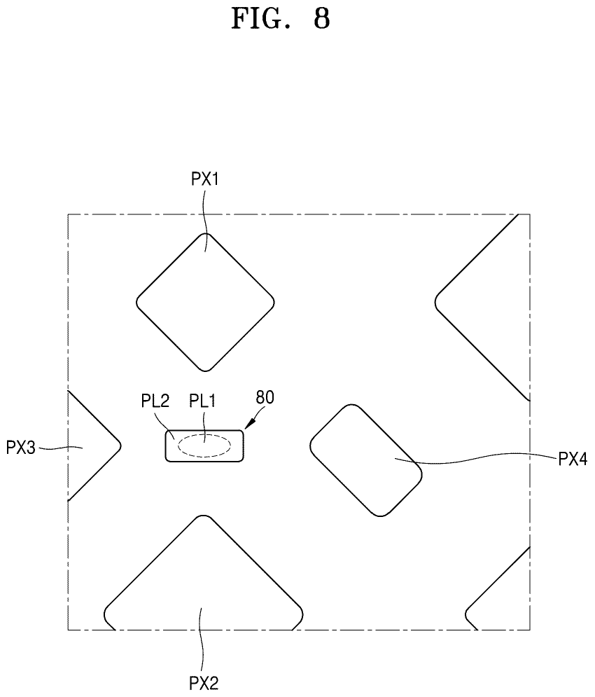

FIG. 8 is a schematic plan view of an arrangement of a spacer 80 in the case where a pixel configuration of the display panel of FIG. 1 is a first configuration. For reference, in the description of FIG. 8, contents identical to or repeating those described with reference to FIGS. 1 to 7 may be omitted.

As an example, the first configuration may be a diamond configuration. In this case, a first pixel PX1, a second pixel PX2, a third pixel PX3, and a fourth pixel PX4 may be arranged to be apart from each other in a diamond shape. The spacer 80 may be arranged between the first pixel PX1, the second pixel PX2, the third pixel PX3, and the fourth pixel PX4. The spacer 80 may be arranged to be apart by a preset distance from the first pixel PX1, the second pixel PX2, the third pixel PX3, and the fourth pixel PX4. The second protective layer PL2 may be damaged by the mask used in the manufacturing process, and as a result, a portion of the first protective layer PL1 may be exposed.

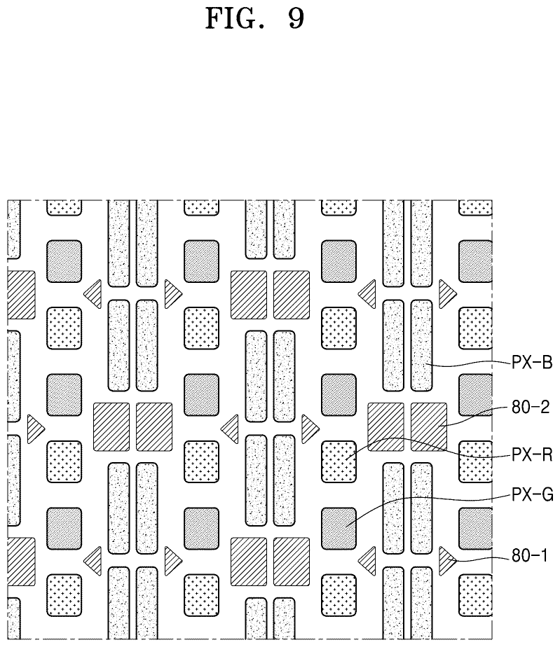

FIG. 9 is a schematic plan view of an arrangement of a spacer in the case where a pixel configuration of the display panel of FIG. 1 is a second configuration. For reference, in the description of FIG. 9, contents identical to or repeating those described with reference to FIGS. 1 to 8 may be omitted.

As an example, the second configuration may be a stripe configuration. In this case, a blue-based pixel PX—B may have an elongated shape in a plan view, and at least two blue-based pixels PX—B may be arranged adjacent to each other. In a plan view, a first spacer 80-1 and/or a second spacer 80-2 may be arranged between a blue-based pixel PX—B, a red-based pixel PX—R, and a green-based pixel PX-G. Each of the first spacer 80-1 and the second spacer 80-2 may be one of many examples of the spacer 80.

In a plan view, the first spacer 80-1 and the second spacer 80-2 may have various shapes. FIG. 9 shows the first spacer 80-1 having a triangular shape and the second spacer 80-2 having a quadrangular shape in a plan view as examples. The second spacer 80-2 having a quadrangular shape may be arranged side by side to be adjacent to another spacer having the same shape in a plan view.

Although omitted for convenience of description and illustration of the drawings, it may be obvious understood that the first protective layer PL1 and the second protective layer PL2 are disposed on the upper surfaces of the first spacer 80-1 and the second spacer 80-2. Depending on the case, a portion of the first protective layer PL1 may be exposed to the outside of the second protective layer PL2 as shown in FIG. 8.

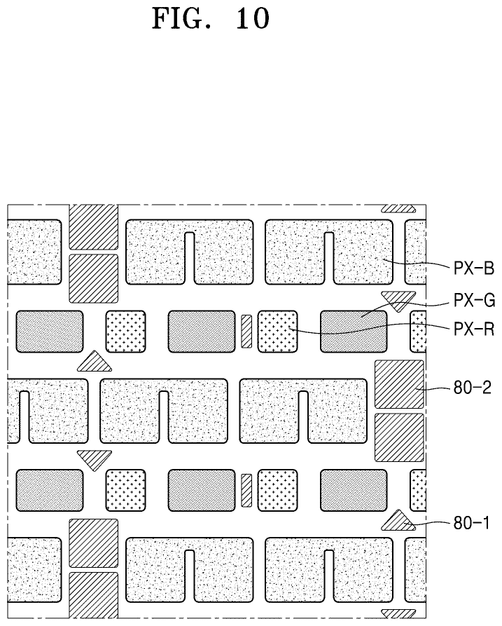

FIG. 10 is a schematic plan view of an arrangement of a spacer in the case where a pixel configuration of the display panel of FIG. 1 is a third configuration. For reference, in the description of FIG. 10, contents identical to or repeating those described with reference to FIGS. 1 to 9 may be omitted.

As an example, the third configuration may be a configuration mainly used in the display panel for an automobile. In this case, a blue-based pixel PX—B, a red-based pixel PX—R, and a green-based pixel PX-G may generally have a quadrangular shape in a plan view. At least two blue-based pixels PX—B may be arranged to be adjacent to each other.

In a plan view, the first spacer 80-1 and/or the second spacer 80-2 may be arranged between a blue-based pixel PX—B, a red-based pixel PX—R, and a green-based pixel PX-G. In a plan view, the first spacer 80-1 and/or the second spacer 80-2 may have various shapes in addition to a triangle and a quadrangle. FIG. 10 shows the first spacer 80-1 having a triangular shape and the second spacer 80-2 having a quadrangular shape in a plan view as examples. The second spacer 80-2 having a quadrangular shape may be arranged side by side with another quadrangular spacer having the same shape in a plan view.

Although omitted for convenience of description and illustration of the drawings, it may be obvious understood that the first protective layer PL1 and the second protective layer PL2 are disposed on the upper surfaces of the first spacer 80-1 and the second spacer 80-2. Depending on the case, a portion of the first protective layer PL1 may be exposed to the outside of the second protective layer PL2 as shown in FIG. 8.

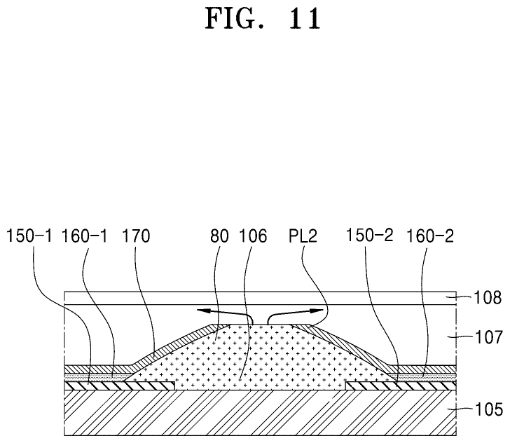

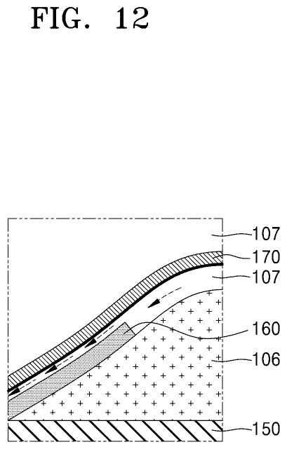

FIG. 11 is a schematic cross-sectional view of an outgassing phenomenon occurring in a spacer of a display apparatus according to a comparative example, and FIG. 12 is a photo showing that a filler of a display apparatus according to a comparative example penetrates into a pixel electrode.

A display apparatus according to a comparative example does not include the first protective layer PL1 and does not include the trench TR. In the case where the first protective layer PL1 is not present as in the display apparatus according to a comparative example, the second protective layer PL2 may be pressed or damaged by the mask used in the manufacturing process, and as a result, the upper surface of the spacer 80 may be exposed and be in direct contact with the filler 107. Accordingly, as shown in FIG. 11, a phenomenon that an inner gas may be emitted to the outside through the spacer 80 may occur.

Furthermore, in the case where the pixel-defining layer 106 not including the trench TR is provided, the filler 107 may easily penetrate between the spacer 80 and the opposite electrode layer 170. Accordingly, as shown in FIG. 12, the filler 107 penetrating between the spacer 80 and the opposite electrode layer 170 may easily penetrate into the neighborhood of the pixel electrode, and as a result, the filler 107 may influence an organic light-emitting element and cause defects in the pixel itself. Defects in the pixel itself caused by the filler 107 are mainly caused by dark spots occurring on the screen.

Accordingly, it is important to prevent the penetration of the filler 107.

The trench TR of FIGS. 4 to 7 may perform a role of preventing the penetration of the filler 107. The shape of the trench TR in the cross-sectional view may hinder the filler 107 reaching the intermediate layer 160. In addition, because the first protective layer PL1 covers the upper surface of the spacer 80, introduction of the filler 107 through the upper surface of the spacer 80 may be prevented.

TABLE 1

| | | | Panels in | | |
|---|---|---|---|---|---|
| | | | which | | |
| | Input | | defective cells | | |
| | number of | | occur | | |
| Condition | panels | | (uHAST 500 hr) | | Remark |
| Trench X | 20 | ea | 20 | ea | Total peeling possible |
| First | | | | | Dark spots are present |
| protective | | | | | when observed with the |
| layer X | | | | | naked eye |
| (condition 1) | | | | | |
| Trench O | 5 | ea | 5 | ea | Total peeling possible |
| First | | | | | Dark spots are present |
| protective | | | | | when observed with the |
| layer X | | | | | naked eye |
| (condition 2) | | | | | |
| Trench O | 14 | ea | 0 | ea | Peeling X |
| First | | | | | Dark spots are absent |
| protective | | | | | when observed with the |
| layer O | | | | | naked eyes |
| (condition 3) | | | | | |

According to [Table 1], experiments on display panels with the same specifications under three conditions and the resulting results are shown.

‘Condition 1’ denotes a condition in which the trench TR is absent and the first protective layer PL1 is absent. A display panel in condition 1 may be a panel formed by the same process as a process of forming spacers under a different condition and by a manufacturing method in which a process of forming the trench TR and a process of forming the first protective layer PL1 are omitted. Unbiased highly accelerated test (uHAST) was performed on 20 display panels in condition 1 for 500 hours. That is, a reliability test was performed under a high-temperature environment (temperature: 85° C., humidity: 85%). In this case, peeling phenomenon was observed and dark spots occurred in all tested display panels (20ea). Peeling may denote a phenomenon that an interval between the intermediate layer 160 and the opposite electrode 170 increases due to penetration of the filler.

‘Condition 2’ denotes a condition in which the trench TR is formed and the first protective layer PL1 is absent. A display panel in condition 2 may be a panel formed by the same process as a process of forming spacers under a different condition and by a manufacturing method in which a process of forming the trench TR is performed and a process of forming the first protective layer PL1 is omitted. Unbiased highly accelerated test (uHAST) was performed on 5 display panels in condition 2 for 500 hours. That is, a reliability test was performed under a high-temperature environment (temperature: 85° C., humidity: 85%). In this case, peeling phenomenon was observed and dark spots occurred in all tested display panels (5ea). However, in uHAST performed for 264 hours, a peeling phenomenon and dark spots were observed in only three display panels.

‘Condition 3’ denotes a condition in which the trench TR is formed and the first protective layer PL1 is formed. A display panel in condition 3 may be a panel formed by the same process as a process of forming spacers under a different condition and by a manufacturing method in which a process of forming the trench TR and a process of forming the first protective layer PL1 are performed. That is, a display panel in condition 3 may be a display panel of FIG. 7.

uHAST was performed on 14 display panels in condition 2 for 500 hours. That is, a reliability test was performed under a high-temperature environment (temperature: 85° C., humidity: 85%). In this case, peeling phenomenon was not observed and dark spots were not observed with naked eyes in all tested display panels (14ea).

In conclusion, in condition 2, defects were confirmed in only some panels in uHAST for 264 hours, but defects were observed in all panels in uHAST for 500 hours. In condition 3, defects were not observed even in uHAST for 500 hours. As described above, in the display panel in which the trench TR is formed, it is confirmed that introduction of the filler 107 is partially prevented, and in the display panel in which the trench TR and the first protective layer PL1 are formed, it is confirmed that introduction of the filler 107 is prevented.

For reference, in the experiments of [Table 1], the process was performed in which the display panels of the same standard were used, and the masks of the same standard were used and disposed on the spacer 80.

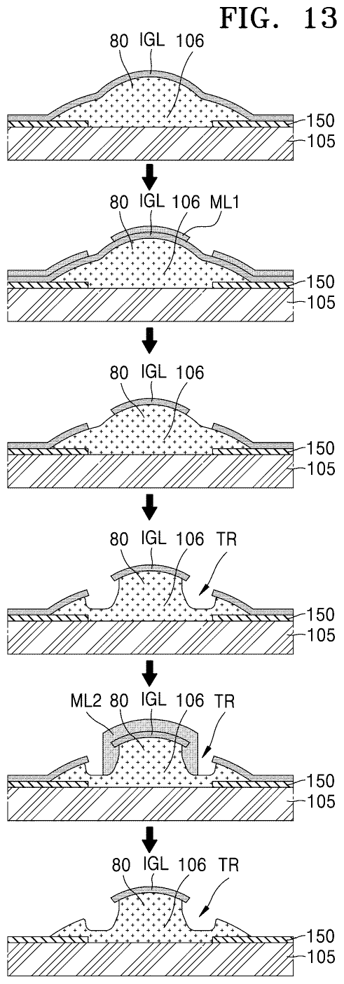

FIG. 13 is a view showing an example of a process of forming the spacer and the first protective layer of FIGS. 4 to 7. For reference, in the description of FIG. 13, contents identical to or repeating those described with reference to FIGS. 1 to 12 may be omitted.

The display apparatus according to an embodiment may be manufactured by using a manufacturing method including a process of forming the first protective layer PL1 on and the trench TR in the pixel-defining layer 106 on which the spacer 80 is disposed. For convenience of description, in the method of manufacturing the display apparatus or the display panel 10 entirely, only the process (referred to as the manufacturing method, hereinafter) of forming the first protective layer PL1 on and the trench TR in the pixel-defining layer 106 on which the spacer 80 is disposed is described.

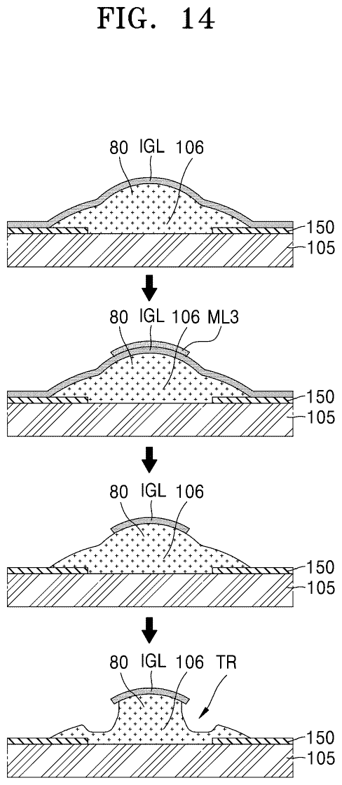

The manufacturing method described with reference to FIG. 13 may be a process of forming the first protective layer PL1 on and the trench TR in the pixel-defining layer 106 on which the spacer 80 is disposed by using two masks. However, the depth of the trench TR formed by the process of FIG. 13 is deeper, and the depth of a trench TR formed by a process of FIG. 14 described below is relatively not deep. Accordingly, to more clearly implement the role of the trench TR, the process of FIG. 13 may be performed.

The manufacturing method may include preparing the second organic insulating layer 105, the pixel electrode layer 150 on the second organic insulating layer 105, the pixel-defining layer 106 disposed on the pixel electrode layer 150 and covering the pixel electrode layer 150, and the spacer 80 disposed on the pixel-defining layer 106.

As shown in FIG. 13, the manufacturing method may further include forming a material layer IGL covering the upper surfaces of the pixel-defining layer 106 and the spacer 80. The material layer IGL may denote a layer for making the first protective layer PL1. Accordingly, the material layer IGL may include IZGO or include a material having an etching selectivity different from an etching selectivity of a material forming the pixel-defining layer 106.

As shown in FIG. 13, the manufacturing method may further include an operation of forming a first photoresist layer ML1 having a pattern of a preset shape on the material layer IGL. The first photoresist layer ML1 may have a pattern of a preset shape to form the trench TR. Accordingly, the photoresist layer ML1 may not be arranged in a region corresponding to the trench TR to be formed.

As shown in FIG. 13, the manufacturing method may further include an operation of etching the material layer IGL based on the pattern of the preset shape. The material layer IGL in a region corresponding to the trench TR to be formed in the pixel-defining layer 106 may be etched by the operation of etching the material layer IGL. As a result, only the material layer IGL remains other than the corresponding area of the trench TR to be formed in the pixel defining layer 106.

As shown in FIG. 13, the manufacturing method may further include an operation of performing a dry etching process on the pixel-defining layer 106. As a result of performing a dry etching process, the trench TR may be formed in an undercut structure. In this case, in a condition used in the dry etching process, an etching selectivity of a material forming the material layer IGL may be less than an etching selectivity of a material forming the pixel-defining layer 106. As a result, the lateral surface of the spacer 80 is formed in an undercut structure, and the trench TR may be formed in the pixel-defining layer 106. In other words, the material layer IGL may serve as a mask layer having an etching pattern for forming the trench TR.

As shown in FIG. 13, the manufacturing method may further include an operation of forming a second photoresist layer ML2 covering a region of the material layer IGL disposed on the spacer 80 after performing the dry etching process. The second photoresist layer ML2 may completely cover the region of the material layer IGL disposed on the spacer 80. As an example, the second photoresist layer ML2 may cover not only the upper surface and the lateral surface of a region of the material layer IGL disposed on the spacer 80 but also the lower surface of the edge of spacer 80 exposed by the undercut structure. In addition, the second photoresist layer ML2 may cover the lateral surface of the spacer 80 and a portion of the trench TR together.

As shown in FIG. 13, the manufacturing method may further include an operation of etching the rest of the material layer IGL other than a region of the material layer IGL covered by the second photoresist layer ML2. As a result, only a region of the material layer IGL corresponding to the first protective layer PL1 may remain and the rest may be removed. Accordingly, the first protective layer PL1 covering the upper surface of the spacer 80 may be finally formed. The second photoresist ML2 remaining after the etching process may be removed.

FIG. 14 is a view showing another example of a process of forming the spacer and the first protective layer of FIGS. 4 to 7. For reference, in the description of FIG. 14, contents identical to or repeating those described with reference to FIGS. 1 to 13 may be omitted.

The display apparatus according to an embodiment may be manufactured by using a manufacturing method including a process of forming the first protective layer PL1 and the trench TR on the pixel-defining layer 106 on which the spacer 80 is disposed. For convenience of description, in the method of manufacturing the display apparatus or the display panel 10 entirely, only the process (referred to as the manufacturing method, hereinafter) of forming the first protective layer PL1 and the trench TR on the pixel-defining layer 106 on which the spacer 80 is disposed is described.

In addition, the manufacturing method described with reference to FIG. 14 may be a process of forming the first protective layer PL1 and the trench TR in the pixel-defining layer 106 on which the spacer 80 is disposed by using one mask and six operations. However, as confirmed in FIGS. 13 and 14, the depth of the trench TR formed by the process of FIG. 13 is deeper, and the depth of the trench TR formed by the process of FIG. 14 may be relatively not deep.

The manufacturing method may include preparing the second organic insulating layer 105, the pixel electrode layer 150 on the second organic insulating layer 105, the pixel-defining layer 106 disposed on the pixel electrode layer 150 and covering the pixel electrode layer 150, and the spacer 80 disposed on the pixel-defining layer 106.

As shown in FIG. 14, the manufacturing method may further include forming a material layer IGL covering the upper surfaces of the pixel-defining layer 106 and the spacer 80. The material layer IGL may denote a layer for making the first protective layer PL1. Accordingly, the material layer IGL may include IZGO or include a material having an etching selectivity different from an etching selectivity of a material forming the pixel-defining layer 106.

As shown in FIG. 14, the manufacturing method may further include an operation of forming a photoresist layer ML3 having a pattern of a preset shape on the material layer IGL. The photoresist layer ML3 may have a pattern of a preset shape corresponding to the first protective layer PL1 to form the first protective layer PL1. Accordingly, the photoresist layer ML3 may not be arranged in a region other than a region in which the first protective layer PL1 is to be arranged.

As shown in FIG. 14, the manufacturing method may further include an operation of etching the material layer IGL based on the pattern of the preset shape. The remaining region of the material layer IGL excluding the region corresponding to the first protective layer PL1 to be formed on the spacer 80 may be etched by the operation of etching the material layer IGL. As a result, the material layer IGL is disposed on the spacer 80, and only a portion of the material layer IGL corresponding to the first protective layer PL1 covering the upper surface of the spacer 80 remains. As a result, the first protective layer PL1 is formed.

As shown in FIG. 14, the manufacturing method may further include an operation of performing a dry etching process on the pixel-defining layer 106. As a result of performing a dry etching process, the trench TR may be formed in an undercut structure. In this case, in a condition used in the dry etching process, an etching selectivity of a material forming the material layer IGL may be less than an etching selectivity of a material forming the pixel-defining layer 106. As a result, the lateral surface of the spacer 80 is formed in an undercut structure, and the trench TR may be formed in the pixel-defining layer 106.

However, unlike the manufacturing method of FIG. 13, because the manufacturing method of FIG. 14 does not use a separate photoresist layer, the depth of the trench TR formed may be relatively shallow.

According to an embodiment, the display apparatus configured to prevent an emission phenomenon of a gas occurring in the spacer may be implemented. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
at least one thin-film transistor disposed on the substrate;
a pixel electrode layer disposed on the at least one thin-film transistor and including at least one pixel electrode;
a pixel-defining layer disposed on the pixel electrode layer and covering edges of the at least one pixel electrode;
a spacer disposed on the pixel-defining layer; and
a first protective layer disposed on the spacer,
wherein the pixel-defining layer includes a trench arranged around the spacer.

2. The display apparatus of claim 1, further comprising:
an opposite electrode layer disposed on the pixel-defining layer; and
a second protective layer disposed on the first protective layer.

3. The display apparatus of claim 2, wherein the second protective layer and the opposite electrode layer include a same material, the second protective layer being separated from the opposite electrode layer.

4. The display apparatus of claim 2, further comprising:
an encapsulation layer disposed on the opposite electrode layer and the second protective layer; and
a filler disposed between the opposite electrode layer and the encapsulation layer and disposed between the second protective layer and the encapsulation layer.

5. The display apparatus of claim 4, wherein the first protective layer covers an upper surface of the spacer.

6. The display apparatus of claim 2, wherein at least a portion of lateral surfaces of the spacer is in contact with the filler, between the opposite electrode layer and the second protective layer.

7. The display apparatus of claim 6, wherein, in a plan view, the spacer is surrounded by the trench.

8. The display apparatus of claim 2, wherein the opposite electrode layer covers an inner surface and a bottom surface of the trench.

9. The display apparatus of claim 1, wherein the pixel electrode layer includes a first pixel electrode and a second pixel electrode apart from the first pixel electrode.

10. The display apparatus of claim 9, wherein, in a plan view, the spacer is arranged between the first pixel electrode and the second pixel electrode.

11. The display apparatus of claim 9, wherein the pixel-defining layer covers edges of the first pixel electrode, includes a first opening above at least a central portion of the first pixel electrode, covers edges of the second pixel electrode, and includes a second opening above at least a central portion of the second pixel electrode.

12. The display apparatus of claim 11, wherein, in a plan view, the spacer is arranged between the first opening and the second opening.

13. The display apparatus of claim 2, wherein the opposite electrode layer and the second protective layer include a same material and have a same layered structure.

14. The display apparatus of claim 1, wherein the first protective layer includes indium gallium zinc oxide (IGZO).

15. The display apparatus of claim 1, wherein a material forming the first protective layer has an etching selectivity different from an etching selectivity of a material forming the pixel-defining layer.

16. The display apparatus of claim 1, wherein the first protective layer has a convex shape facing upward.

17. The display apparatus of claim 2, wherein the second protective layer exposes at least a central portion of the first protective layer to outside.

18. The display apparatus of claim 17, wherein an upper surface of at least a central portion of the first protective layer is flat.

19. The display apparatus of claim 1, wherein the spacer and the pixel-defining layer include a same material.

20. A display apparatus comprising:
a substrate;
at least one thin-film transistor disposed on the substrate;
a pixel electrode layer disposed on the at least one thin-film transistor and including at least one pixel electrode; and
a pixel-defining layer disposed on the pixel electrode layer and covering edges of the at least one pixel electrode;
wherein the pixel-defining layer comprises:
a spacer region having a first thickness;
a protrusion region having a second thickness less than the first thickness; and
a trench region arranged between the spacer region and the protrusion region, in a plan view, and having a third thickness less than the second thickness, and
wherein a first protective layer is disposed on the pixel-defining layer in the spacer region.

21. The display apparatus of claim 20, further comprising:
an opposite electrode layer on the pixel-defining layer in the protrusion region and the trench region; and
a second protective layer disposed on the first protective layer.

22. The display apparatus of claim 21, wherein the second protective layer and the opposite electrode layer include a same material, the second protective layer being separated from the opposite electrode layer.

23. The display apparatus of claim 21, further comprising:
an encapsulation layer disposed on the opposite electrode layer and the second protective layer; and
a filler disposed between the opposite electrode layer and the encapsulation layer and disposed between the second protective layer and the encapsulation layer.

24. The display apparatus of claim 20, wherein, in a plan view, the spacer region is surrounded by the trench region.

25. The display apparatus of claim 21, wherein the second protective layer exposes at least a central portion of the first protective layer.

26. The display apparatus of claim 25, wherein an upper surface of at least a central portion of the first protective layer is flat.
